(19) United States
(12) Patent Application Publication
(10) Pub. No.: US 2012/0325318 A1
(43) Pub. Date: Dec. 27, 2012

(54) SOLAR CELL AND FABRICATION METHOD THEREOF

(75) Inventors: Hsin-Fei Meng, Hsinchu (TW); Hsiao-Wen Zan, Hsinchu (TW); Sheng-Fu Horng, Hsinchu (TW); Yu-Chiang Chao, Hsinchu (TW); Yuan-Pai Lin, Hsinchu (TW)

(73) Assignee: NATIONAL CHIAO TUNG UNIVERSITY, Hsinchu City (TW)

(21) Appl. No.: 13/167,068

(22) Filed: Jun. 23, 2011

(51) Int. Cl. H01L 51/46; H01L 31/18

(52) U.S. Cl. 136/263; 438/57; 257/E31.001

(57) ABSTRACT

A solar cell is provided that an extremely thin light absorber is formed between a n-type semiconductor layer and a p-type semiconductor layer such that the light absorber is used to absorb solar energy, while the p-type semiconductor layer may not absorb light. After separation of electrons and holes, the carriers will not recombine during the conduction, in order to avoid energy loss.

### TECHNICAL FIELD

The present invention relates generally to solar cells, and more particularly, to a solar cell for increasing power conversion efficiency and fabrication method thereof.

### BACKGROUND

In recent years, human beings are facing the crisis of energy shortage and global warming, and the development of solar power are getting more and more attention. At present, solar cells are primarily composed of single crystalline silicon and polysilicon, and the energy is mainly generated based on the photo-conductive effect and the internal electric field, in which the photo-conductive effect refers to a phenomenon of the light facilitating the electric conductivity.

When an electron acquires enough energy to break away from its atom, the electron becomes a free electron and leaves behind a vacancy what is called a hole. In general, the more the number of free electrons and holes, the better the electric conductivity, which increases an output current. Therefore, when the sunlight is stronger, the more number the free electrons and holes are formed, and the output current thus becomes larger.

If there are merely the free electrons and holes being produced, they will lose the energy owing to factors, such as collision, and recombine with each other with no use. By introducing an electric field, the free electrons and holes can be separated and electric current can be generated, so as to effectively take advantage of the free electrons and holes. There are numerous ways of generating the electric field, such as: a PN junction, or metal semiconductor junction, and the like, in which the most commonly method is the PN junction.

An n-type semiconductor is produced when a pentavalent impurity is added into a silicon crystal, and a p-type semiconductor is produced when a trivalent impurity is added into a silicon crystal. If the n-type and p-type semiconductors contact with each other and form the PN junction, the diffusion occurs across the junction since the concentrations of these two semiconductors are different. In other words, the free electrons diffuse from the n-type semiconductor to the p-type semiconductor, and the holes diffuse from the p-type semiconductor to n-type semiconductor, such that the n-type semiconductor near the junction losing electrons becomes positively charged, and the p-type semiconductor gaining electrons becomes negatively charged.

As the charge density is not uniform, the electric field occurs near the PN junction. If the free electrons or holes are generated in the electric field due to the electric field, the free electrons move toward the n-type semiconductor, while the holes move toward the p-type semiconductor. As such, there will be a region called a depletion zone because of depleting free charge carriers.

The photoelectric effect refers to a principle of photoelectric power conversion. While the light is incident upon the depletion zone and exciting electrons of the silicon atom to generate free electrons and holes, the charges in the solar cell will move towards to two ends away from the junction under the electric field; therefore, energy in the cell can be used by connecting a circuit to the ends.

In the art as disclosed in U.S. Pat. No. 4,281,053, an organic solar cell with two layers PN junction structure is fabricated by vapor deposition. However, the area of the PN junction is not large enough to effectively increase the output current.

Therefore, a solar cell has been developed in the art, referring to FIG. 1A or the disclosure of U.S. Pat. No. 7,763,794. For the solar cell 1, a glass substrate 10 is sequentially formed with a transparent conductive layer 11, an n-type semiconductor layer 12, a p-type semiconductor layer 13 and an electrode layer 14. The material for forming the transparent conductive layer 11 may be indium tin oxide (ITO), and the material for forming the n-type semiconductor layer 12 may be zinc oxide (ZnO). With a higher surface area of the glass substrate 10, the n-type semiconductor layer 12 and p-type semiconductor layer 13 both have a similar surface pattern (i.e., a high surface area), along with an increased area of the PN junction so as to raise the photocurrent.

However, in the conventional solar cell 1, since the p-type semiconductor layer 13 is required to have the capability of both high carrier mobility and strong light-absorbing capability, the probability of carrier recombination cannot be reduced which significantly causes loss in power conversion, but also the difficulty of the material design and synthesis is still introduced.

Furthermore, an organic solar cell has been developed using bulk heterojunction structure (referring to High-efficiency solution processable polymer photovoltaic cells by self-organization of polymer blends, vol. 4, the Natural Materials, November 2005), in which the components of the n-type and p-type semiconductor layers are uniformly combined to overcome the complexity in material design and synthesis issues, and thus to improve the power conversion efficiency. Nevertheless, since the p-type semiconductor layer is still required to have the capability of both high carrier mobility and strong light-absorbing capability, the carriers will still tend to recombine after the separation of electrons and holes during the conduction, and thereby to result in energy loss.

Afterwards, an organic solar cell has been developed (referring to FIG. 1B, or “Improved performance of poly (3-hexylthiophene)/zinc oxide hybrid photovoltaic modified with interfacial nanocrystalline cadmium sulfide” vol. 95, the Applied Physics Letters, 2009). In a solar cell 1′, on a glass substrate 10 sequentially are formed a transparent conductive layer 11, a n-type semiconductor layer 12, a nanocrystalline layer 15, a p-type semiconductor layer 13′ and an electrode layer 14. The material of the n-type semiconductor layer 12 is zinc oxide (ZnO), the material of the nanocrystalline layer 15 is cadmium sulfide (CdS), and the material of the p-type semiconductor layer 13′ is poly(3-hexylthiophene) (P3HT). By way of the introduction of the CdS layer, the solar cell 1′ doubles its voltage, so that the overall power of the solar cell 1′ can be increased.

However, since the p-type semiconductor layer is required to have the capability of both high carrier mobility and strong light-absorbing capability, the carriers will still recombine, after their separation, during the conduction and leading to energy loss.

From the foregoing, although either scholars or industry are constantly looking for ways to enhance power conversion efficiency, the problem of “the carriers recombine after their separation during the conduction and leading to energy loss” are not resolved, and thus are incapable of significantly enhancing the power conversion efficiency of the solar cell. In this regard, it has become an important issue in effectively improving the energy loss of the solar cell for enhancing the conversion efficiency of the solar cell.

### SUMMARY OF THE INVENTION

In view of the above-mentioned disadvantages of the prior techniques, an embodiment of the present invention is to provide a solar cell having a first electrode layer; a n-type semiconductor layer; a light absorber; a p-type semiconductor layer, and a second electrode layer. The light absorber is disposed between the n-type semiconductor layer and the p-type semiconductor layer for absorbing light energy, so that the p-type semiconductor layer is not required to absorb light, that is, the p-type semiconductor layer is only required to have the high carrier mobility without having strong light-absorbing capability. As such, the probability of carrier recombination during conduction can be avoided and energy loss can be reduced.

In the aforementioned solar cell, the thickness of the light absorber is less than the thickness of the n-type semiconductor layer and the thickness of the p-type semiconductor layer. The n-type semiconductor layer is made of an inorganic material and the p-type semiconductor layer is made of an organic material, or the n-type semiconductor layer is made of an organic material and the p-type semiconductor layer is made of an inorganic material.

Furthermore, to increase the area of the PN junction, a plurality of recesses, such as a porous structure, are formed on a surface of the n-type semiconductor layer contacting the light absorber, and the light absorber is formed in the recesses.

Also, the dopant can be added to the n-type semiconductor layer or the p-type semiconductor layer for enhancing the conductivity.

In addition, the invention provides a fabrication method of a solar cell, which will be described as follows.

### BRIEF DESCRIPTION OF DRAWINGS

FIG. 1A and FIG. 1B are cross-sectional views of the different types of the prior art;

FIG. 2A is a cross-sectional view of a solar cell according to an embodiment of the present invention;

FIG. 2B is a cross-sectional view of another type of the n-type semiconductor layer of the solar cell according to the embodiment of the present invention; and

FIGS. 3A to 3C are cross-sectional views of the process of the porous structure on the surface of the n-type semiconductor layer of the solar cell according to an embodiment of the present invention.

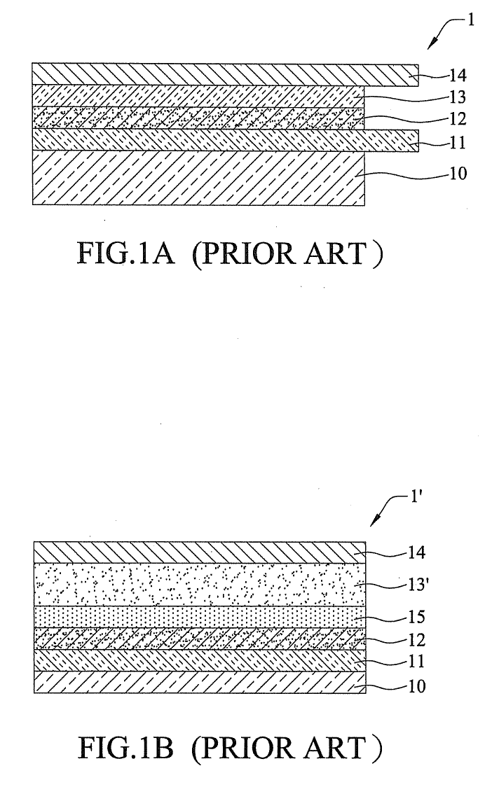

### DETAILED DESCRIPTION OF PREFERRED EMBODIMENTS

The following illustrative embodiments are provided to illustrate the present invention, and these and other advantages and effects can be apparently understood by those in the art after reading the present invention. The present invention can also be performed or applied by other different embodiments. The details of the specification may be carried out based on different points and applications, and numerous modifications and variations can be devised without departing from the spirit of the present invention.

Furthermore, the present invention of the instructions are simplified schematic diagram, only indicate the basic technical idea of the present invention, so the actual implementation of each component type, quantity and proportion of visual implementation of the requirements change.

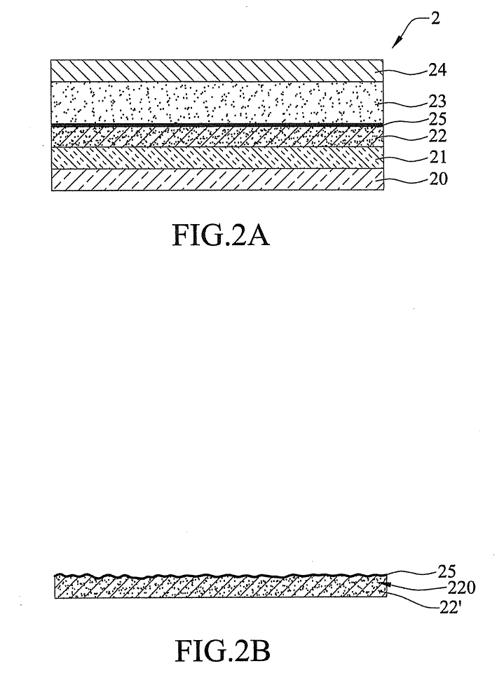

Referring to FIG. 2A, a cross-sectional view of the solar cell is shown according to an embodiment of the present invention.

In an embodiment of the present invention as shown in FIG. 2A, the fabrication method of the solar cell 2 provides a substrate 20 having a first electrode layer 21 formed on a surface thereof, the material of the substrate 20 may be glass, but is not limited thereto. The first electrode layer 21 is a conductive transparent layer, and may be made of a material like indium tin oxide (ITO). Then, an n-type semiconductor layer 22, a light absorber 25, a p-type semiconductor layer 23, and a second electrode layer 24 are sequentially formed on the first electrode layer 21. The light absorber 25 locates between the n-type semiconductor layer 22 and the p-type semiconductor layer 23, and the second electrode layer 24 is formed afterwards by an evaporation process.

Since the solar cell 2 mainly absorbs solar energy by the light absorber 25, and the p-type semiconductor layer 23 and the n-type semiconductor layer 22 are not necessarily to absorb light, as far as the material is considered, a significant difference in capability of absorbing solar light between the p-type semiconductor layer 23 (and n-type semiconductor layer 22) and the absorber 25 is required. For example, the light absorptance of the light absorber 25 is at least about 100 times greater than the p-type semiconductor layer 23 and the n-type semiconductor layer 22, so as to prevent the p-type semiconductor layer 23 and the n-type semiconductor layer 22 from absorbing solar energy. Furthermore, the equation of light absorption A=α·L shows that (where A is intensity, α is absorb coefficient, and L is thickness) the light absorber 25 may choose a material with α much larger than those of the p-type semiconductor layer 23 and the n-type semiconductor layer 22.

Typically, the n-type semiconductor layer 22 of the solar cell 2 may be made of an inorganic material and the p-type semiconductor layer 23 may be made of an organic material, or the n-type semiconductor layer 22 may be made of an organic material and the p-type semiconductor layer 23 may be made of an inorganic material. For example, in the manufacture, because zinc oxide (ZnO) and TFB material (poly(9,9′-dioctylfluorene-co-N (4-butylphenyl)diphenylamine) both have the feature of insignificantly absorption of solar light with a wavelength above 400 nm, each of them can be used for forming the n-type semiconductor layer 22 and p-type semiconductor layer 23, respectively, As such, the n-type semiconductor layer 22 and p-type semiconductor layer 23 do not significantly absorb solar energy, and, when the thicknesses of the ZnO layer and the TFB layer are larger than 400 nm, the feature of insignificant absorption of solar light with the wavelength above 400 nm becomes even more obvious.

Furthermore, in an embodiment of the present invention, since the poly(3-hexylthiophene) (P3HT) or the lead phthalocyanine (PbPC) has the feature of significantly absorbing solar light, both of them can be used as the material of the light absorber 25 for significantly absorbing solar energy.

Therefore, as the material of both the p-type semiconductor layer 23 and the n-type semiconductor layer 22 is different from that of the light absorber 25, the p-type semiconductor layer 23 and the n-type semiconductor layer 22 only absorb relatively a small amount of light, and most of the light is absorbed by the light absorber 25.

Further, concerning the band of energy, after the light absorber 25 absorbs the carrier, the electrons and holes can effectively get into the n-type semiconductor layer 22 and p-type semiconductor layer 23, respectively. That is, there should be no energy barrier between the conduction band of the light absorber 25 and the conduction band of the n-type semiconductor layer 22 or the energy barrier between the conduction band of the light absorber 25 and the conduction band of the n-type semiconductor layer 22 should not be too high, same as that between the light absorber 25 and the p-type semiconductor layer 23.

In this regard, the thickness of the light absorber 25 should not be too thick, in order to avoid recombination after generating the photons (or the photons can not be moved to the n-type semiconductor layer 22 and p-type semiconductor layer 23). Therefore, the thickness of the light absorber 25 is required to be less than the mean free path length of the electron and hole in the light absorber 25, for example, the thickness of the light absorber 25 is less than 30 nm.

If the thickness of the light absorber 25 is too small, e.g., less than the diffusion length thereof, a large number of photons will directly penetrate through the entire structure of the solar cell 2 and reduce the power conversion efficiency. Therefore, when the thickness of the light absorber 25 is approximately equal to the diffusion length of the excitons (i.e., 17 nm), the power conversion efficiency of the solar cell 2 is optimized, such that the thickness of the light absorber 25 is preferred to be about 16 nm. The thickness of the light absorber 25 may be adjusted depending on the material selected and is not limited to the above; however, the thickness of the light absorber 25 is extremely thin relative to the thickness of the n-type semiconductor layer 22 and p-type semiconductor layer 23.

In addition, in terms of energy level, a lowest unoccupied level (i.e., the lowest unoccupied molecular orbital, LUMO) of the light absorber 25 is positioned between a conduction band of the n-type semiconductor layer 22 and a conduction band of the p-type semiconductor layer 23, and a highest occupied level (i.e., the highest occupied molecular orbital, HOMO) of the light absorber 25 is positioned between the conduction band of the n-type semiconductor layer 22 and the conduction band of the p-type semiconductor layer 24, in order to reduce the obstacles of the mobility of the electrons and holes upon the light absorber 25 absorbing the carrier.

Also, the n-type semiconductor layer 22 and p-type semiconductor layer 23 can enhance the conductivity, and the mobility of the carriers, by adding dopants. For example, aluminum (Al) can be added into ZnO as the dopant, while tetrafluorotetracyanoquinodimethane (F4-TCNQ) can be added into the p-type organic semiconductors as the dopant. There are a wide variety of materials capable of enhancing the conductivity and is not limited to the above.

In addition, the thickness of the p-type semiconductor layer 23 can be greater than the thickness of the n-type semiconductor layer 22, but is not limited thereto. The material of forming the second electrode layer 24 may be molybdenum trioxide (MoO3)/aluminum, but the material of the electrode layer is well-known in the art and thus the selection is not limited to the above.

Referring to FIG. 2B, a cross-sectional view of another type of the n-type semiconductor layer 22′ of the solar cell is shown according to the embodiment of the present invention. As shown in FIG. 2B, in order to increase the area of the PN junction, a plurality of recesses 220, such as porous structure, are formed on a surface of the n-type semiconductor layer 22′. Also, the light absorber 25 corresponding in position to the recesses 220 are formed in the recesses 220, so that the area for absorbing light of the light absorber 25 is increased for more effectively absorbing light and enhancing light current.

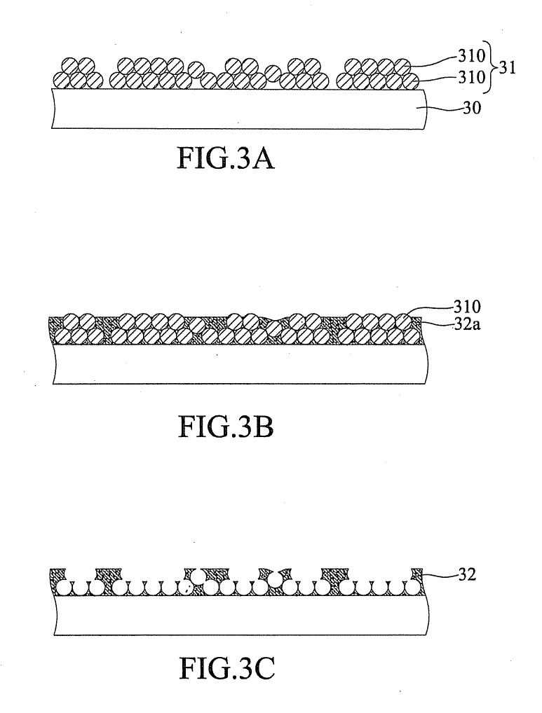

Referring to FIGS. 3A to 3C, a process of forming the porous structure on the surface of the n-type semiconductor layer is provided according to an embodiment of the present invention.

As shown in FIG. 3A, a board 30 is provided (may be the substrate 20 having the first electrode layer 21, or the n-type semiconductor layer 22 with a thinner thickness formed on the first electrode layer 21), and a resist layer 31 is formed on a part of the surface of the board 30, such as on the surface of the first electrode layer 21, allowing a part of the first electrode layer 21 to be connected to the outside. In an embodiment, the resist layer 31 is composed of the polystyrene (PS) ball 310. The resist layer 31, which is composed of at least one or more layers of PS ball 310, is formed by spin-coating a solvent having the PS ball 310 on the board 30.

As shown in FIG. 3B, a n-type semiconductor material 32a, such as the precursor of ZnO, is coated on the PS ball 310 and on the surface of the board 30 not covered with the PS ball 310, that is, the surface of the first electrode layer 21 connected to the outside.

As shown in FIG. 3C, the PS ball 310 is evaporized by heating or the resist layer 31 is dissolved by a solvent, so as to form the ZnO layer 32 (i.e., the n-type semiconductor layer) having the porous structure. However, there are a wide variety of ways of forming the porous structure such that the formation of the porous structure is not limited to the above.

Later, as mentioned above, the light absorber 25 is formed on the surface of the n-type semiconductor layer 22, so as for the light absorber 25 to be thereby formed in the recesses 220 of the surface of the n-type semiconductor layer 22.

In summary, the solar cell and fabrication method according to the embodiments of the present invention provides a light absorber between an n-type semiconductor layer and a p-type semiconductor layer, such that the light absorber absorbs solar energy while the p-type and n-type semiconductor layers transfer carriers. Accordingly, the carriers will not be recombined with each other in conduction upon the separation, so as to avoid energy loss therein and to thereby achieve the purpose of enhancing the conversion efficiency.

Furthermore, by controlling the conduction band and the valence band of the material of the light absorber, there is no energy barrier between the light absorber and the n-type and the p-type semiconductor layers, or the barrier is reduced, so that the electron and hole can be moved into the n-type and the p-type semiconductor layers.

Also, since the plurality of recesses are formed on an exposed surface of the n-type semiconductor layer, the area of the PN junction is increased and so the absorption area.

Furthermore, the mobility of the carriers and carrier concentration of the n-type and the p-type semiconductor layers are enhanced by adding dopants.

While the present invention has been described in terms of what are presently considered to be the most practical and preferred embodiments, it is to be understood that the present invention need not limit to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A solar cell comprising:
a first electrode layer;
an n-type semiconductor layer formed on the first electrode layer;
a light absorber formed on the n-type semiconductor layer;
a p-type semiconductor layer formed on the light absorber, such that the light absorber is disposed between the n-type semiconductor layer and the p-type semiconductor layer, and the light absorber is less in thickness than both the n-type semiconductor layer and the p-type semiconductor layer; and
a second electrode layer formed on the p-type semiconductor layer.

2. The solar cell of claim 1, wherein the n-type semiconductor layer is made of an inorganic material and the p-type semiconductor layer is made of an organic material, or the n-type semiconductor layer is made of an organic material and the p-type semiconductor layer is made of an inorganic material.

3. The solar cell of claim 1, wherein the n-type semiconductor layer has a dopant, or the p-type semiconductor layer has a dopant, or both the n-type and p-type semiconductor layers have dopants.

4. The solar cell of claim 1, wherein the thickness of the n-type semiconductor layer is greater than 400 nm, or the thickness of the p-type semiconductor layer is greater than 400 nm.

5. The solar cell of claim 1, wherein a plurality of recesses are formed on a surface of the n-type semiconductor layer contacting the light absorber, and the light absorber is formed in the recesses.

6. The solar cell of claim 1, wherein an energy level of lowest unoccupied molecular orbital (LUMO) of the light absorber is between a conduction band of the n-type semiconductor layer and a conduction band of the p-type semiconductor layer, and an energy level of highest occupied molecular orbital (HOMO) of the light absorber is between the conduction band of the n-type semiconductor layer and the conduction band of the n-type semiconductor layer.

7. The solar cell of claim 1, wherein the light absorber is poly(3-hexylthiophene) or lead phthalocyanine (PbPc).

8. The solar cell of claim 1, wherein the thickness of the light absorber is less than 30 nm.

9. A fabrication method of a solar cell, comprising the steps of:
providing a substrate having a first electrode layer formed thereon;
forming an n-type semiconductor layer on the first electrode layer;
forming a light absorber on the n-type semiconductor layer;
forming a p-type semiconductor layer on the light absorber, so as for the light absorber to be disposed between the n-type semiconductor layer and the p-type semiconductor layer, wherein the light absorber is less in thickness than both the n-type semiconductor layer and the p-type semiconductor layer; and
forming a second electrode layer on the p-type semiconductor layer.

10. The fabrication method of the solar cell of claim 9, wherein the n-type semiconductor layer is made of an inorganic material and the p-type semiconductor layer is made of an organic material, or the n-type semiconductor layer is made of an organic material and the p-type semiconductor layer is made of an inorganic material.

11. The fabrication method of the solar cell of claim 9, wherein the n-type semiconductor layer has a dopant, or the p-type semiconductor layer has a dopant, or both the n-type and p-type semiconductor layers have dopants.

12. The fabrication method of the solar cell of claim 9, wherein the thickness of the n-type semiconductor layer is greater than 400 nm, or the thickness of the p-type semiconductor layer is greater than 400 nm.

13. The fabrication method of the solar cell of claim 9, wherein a plurality of recesses are formed on a surface of the n-type semiconductor layer contacting the light absorber, and the light absorber is formed in the recesses.

14. The fabrication method of the solar cell of claim 13, wherein formation of the recesses includes:
forming a resistance layer on the first electrode layer, allowing a part of the first electrode layer to be connected to outside;
forming an n-type semiconductor material on the part of the first electrode layer connected to outside; and
removing the resistance layer, so as for the n-type semiconductor material to be formed into the n-type semiconductor layer with the recesses.

15. The fabrication method of the solar cell of claim 14, wherein the resistance layer is removed by heating and evaporation, or by being dissolved in a solvent.

16. The fabrication method of the solar cell of claim 9, wherein a lowest unoccupied gap of the light absorber is positioned between a conduction band of the n-type semiconductor layer and a conduction band of the p-type semiconductor layer, and a highest occupied gap of the light absorber is positioned between a conduction band of the n-type semiconductor layer and a conduction band of the p-type semiconductor layer.

17. The fabrication method of the solar cell of claim 9, wherein the light absorber is poly(3-hexylthiophene) or lead phthalocyanine (PbPc).

18. The fabrication method of the solar cell of claim 9, wherein the thickness of the light absorber is less than 30 nm.
